(19) United States
(12) Patent Application Publication
(10) Pub. No.: US 2024/0194670 A1
(43) Pub. Date: Jun. 13, 2024

(54) ASYMMETRICALLY BONDED INTEGRATED CIRCUIT DEVICES

(71) Applicant: INTERNATIONAL BUSINESS MACHINES CORPORATION, Armonk, NY (US)

(72) Inventors: Ruqiang Bao, Niskayuna, NY (US); Fee Li Lie, Albany, NY (US); Michael P. Belyansky, Halfmoon, NY (US); Matt Malley, Averill Park, NY (US)

(21) Appl. No.: 18/078,245

(22) Filed: Dec. 9, 2022

(51) Int. Cl. H01L 27/06; H01L 21/768; H01L 23/00; H01L 23/48

(52) U.S. Cl. CPC H01L 27/0688; H01L 21/76898; H01L 23/481; H01L 24/32; H01L 24/83; H01L 2224/32145; H01L 2224/83896

(57) ABSTRACT

A multi-layer stacked semiconductor device includes a first integrated circuit device and a bonding insulator layer formed upon the first integrated circuit device. The bonding insulator layer includes an insulating material layer and an etch stop layer. The semiconductor device also includes a second integrated circuit device formed over the first integrated circuit device in a stacked configuration. The semiconductor device also includes a bonding insulator layer formed between the second integrated circuit device and the insulating material layer. The insulating material layer and the bonding insulator layer are bonded adjacent to one another.

### BACKGROUND

The present disclosure is generally in the field of integrated circuit (IC) devices and methods for fabricating integrated circuit devices. More particularly, the present disclosure relates to bonded integrated circuit devices and methods for fabricating the same.

Integrated circuit chips are formed on semiconductor wafers at increasingly smaller scale. In current technology nodes, such as 7, 10 and 14 nanometer technologies, transistor devices are constructed as three-dimensional (3D) field effect transistor (FET) structures. Three-dimensional (3D) monolithic integration by stacking a wafer including one type of FETs (e.g., p-type FETs) on top of a complementary wafer having a second type of FETs (e.g., n-type FETs) is an attractive approach for 5 nm node technology and beyond. In these stacked configurations, one wafer is referred to as a “structural” wafer, and the other wafer stacked thereon is referred to as a “non-structural” wafer.

In typical configurations, there is an insulator layer formed over the FETs on each wafer, and the two wafers are stacked together at an interface joining the two insulator layers. For this interface to result in effective bonding, each insulator layer is typically polished before bonding, which removes some of the insulator layer and smooths the remaining surface. However, polishing an insulator layer on a structural wafer can pose challenges because removing too much of the insulator layer can risk damage to the devices within the structural wafer. This can result in a need to retain a thick insulator layer on the structural wafer after polishing, which can significantly increase the overall thickness of the stacked FET structure. This increase in thickness often leads to a corresponding reduction in device performance.

### SUMMARY

Some embodiments of the present disclosure can be illustrated as a multi-layer stacked semiconductor device. The multi-layer semiconductor device comprises a first integrated circuit device. The multi-layer semiconductor device also comprises a bonding insulator formed upon the first integrated circuit device. The bonding insulator comprises an insulating material layer and an etch-stop layer. The multi-layer stacked semiconductor device also comprises a second integrated circuit device that is formed over the first integrated circuit device in a stacked configuration. The multi-layer stacked semiconductor device also comprises a bonding insulator layer formed between the second integrated circuit device and the insulating material layer. The insulating material layer and the bonding insulator layer are bonded adjacent to one another. In these embodiments, the etch-stop layer in the bonding insulator can be used to create a smooth bonding surface upon the insulating material layer without significantly increasing the thickness of the insulating material layer, leading to an increase in device performance.

Some embodiments of the present disclosure can be illustrated as a semiconductor chip that comprises a multiple-layer stacked semiconductor device such as the multi-layer stacked semiconductor device summarized above. This may enable taking advantage of the increased performance of the multi-layer stacked semiconductor device at the semiconductor-chip level.

Some embodiments of the present disclosure can also be illustrated as a method for fabricating a multi-layer stacked semiconductor device. The method comprises depositing an etch stop layer upon a first integrated circuit device. The method also comprises depositing a sacrificial insulating layer upon the etch stop layer. The method also comprises removing the sacrificial layer. The method also comprises depositing an insulating material layer upon the etch stop layer. The method also comprises bonding a semiconductor template stack to the insulating material layer. This method allows for forming an insulating material layer that is thin and sufficiently smooth for bonding purposes, leading to an increase in device performance.

Some embodiments of the present disclosure can also be illustrated as a more specific version of the above method of fabricating a multi-layer stacked semiconductor device. In the more specific version, removing the sacrificial insulator layer comprises performing chemical-mechanical polishing that is selective to the etch-stop layer. In these embodiments, performing chemical-mechanical polishing to the etch-stop layer can result in a smooth bonding surface upon the insulating material layer when it is formed upon the etch stop-layer.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

Exemplary embodiments of the present disclosure will hereinafter be described in conjunction with the following drawing figures, wherein like numerals denote like elements, and wherein:

FIGS. 1-11 provide cross-sectional views illustrating procedures in the fabrication of a stacked IC device in accordance with the present disclosure; and

FIG. 12 is a process flow diagram illustrating a method for fabricating a stacked IC device in accordance with the present disclosure.

### DETAILED DESCRIPTION

The disclosure will now be described in greater detail by referring to the following discussion and drawings that accompany the present disclosure. It is noted that the drawings of the present disclosure are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present disclosure may be practiced without these specific details. In other instances, well-known structures or processing steps in the fabrication of integrated circuit structures have not been described in detail in order to avoid obscuring the present disclosure.

Exemplary applications/uses to which the present disclosure can be applied include, but are not limited to: transistors for complementary metal-oxide-semiconductor (CMOS) devices, logic devices (e.g., NAND gates, NOR gates, XOR gates, etc.), memory devices (e.g., DRAM, SRAM, flip-flops, etc.), etc.

In various embodiments, the materials and layers can be deposited by physical vapor deposition (PVD), chemical vapor deposition (CVD), atomic layer deposition (ALD), molecular beam epitaxy (MBE), or any of the various modifications thereof, for example, plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PEALD). The depositions can be epitaxial processes, and the deposited material can be crystalline. In various embodiments, formation of a layer may be by one or more deposition processes, where, for example, a conformal layer can be formed by a first process (e.g., ALD, PEALD, etc.) and a fill can be formed by a second process (e.g., CVD, electrodeposition, PVD, etc.).

It is to be understood that the present disclosure will be described in terms of a given illustrative architecture: however, other architectures, structures, substrate materials and process features and steps may be varied within the scope of the present disclosure. It should be noted that certain features may not be shown in all figures for the sake of clarity. This is not intended to be interpreted as a limitation of any particular embodiment, or illustration, or scope of the claims.

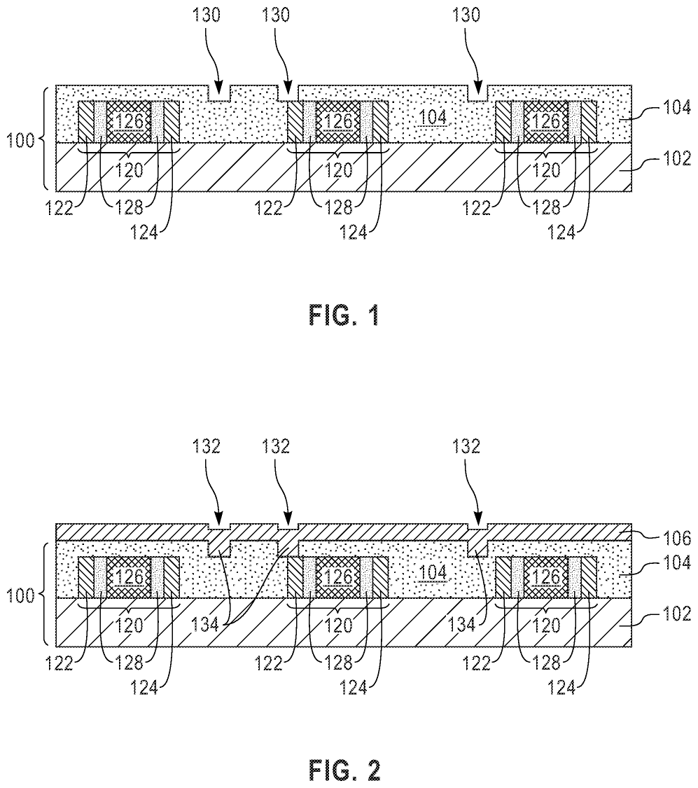

Turning now to FIG. 1, illustrated is a cross-section view of a first level or “structural” integrated circuit (IC) device 100 having a plurality of field effect transistors (FETs) 120 in accordance with embodiments of the present disclosure, in early stages of fabrication. IC device 100 includes a semiconductor substrate 102 that is formed of a semiconductor material. As used in the present disclosure, the term “material of” when used with respect to a deposited layer means that such layer includes at least that material, but could also possibly include other materials. As such “material of” is used in the “comprising” sense and not the “consisting of” sense. The term “semiconductor” as used herein in connection with the semiconductor material of the substrate 102 (or any other semiconductor material described herein) denotes any material that exhibits semiconductor properties including, for example, Si, Ge, SiGe, SiC, SiGeC, a II/VI compound semiconductor or a III/V compound semiconductor such as, for example, InAs, GaAs, or InP. In one embodiment, the substrate 102 is formed of silicon.

FETs 120 are formed directly adjacent to and in contact with substrate 102. FETs 120 may be spaced apart from one another on the substrate 102 at regular or irregular intervals. Suitable deposition methods for the materials of each FET 120 include, for example, chemical vapor deposition (CVD), plasma enhanced chemical vapor deposition (PECVD), physical vapor deposition (PVD), sputtering, atomic layer deposition (ALD) or other like deposition processes.

Each FET 120 includes a gate structure 126. Each gate structure 126 includes a gate dielectric portion and a gate conductor portion (not separated illustrated in the view of FIG. 1). Furthermore, FETs 120 each include a source region 122 and a drain region 124. Each source region 122 and drain region 124 include a silicon material that includes an appropriate dopant, of either the n-type or the p-type. The source regions 122 and the drain regions 124 are provided in the areas shown in FIG. 1, that is, areas laterals to but not covered by gate structures 126. The source and drain regions 122, 124 are separated from the gate structures 126 using appropriate dielectric spacers 128, which include an insulative material such as silicon oxide. As used herein, any of the source regions 122, drain regions 124, or gate structures 126 may be referred to as “terminals” of the FETs 120.

In some embodiments, first level IC structure 100 may include a (non-illustrated) carrier substrate. The carrier substrate may be provided for mounting a plurality of semiconductor chips to form a first level (or chip level) package structure. In conventional packaging technologies, chip level carrier substrates are constructed using organic laminate build up or ceramic carrier substrate technologies. The material forming the carrier substrate may be any of a variety of insulative or semiconductor materials such as, for example, silicon, fused silica (glass, quartz), ceramic, or another semiconductor or insulator. The first level IC structure 100 of the present disclosure may be configured as a semiconductor-on-insulator (SOI) wafer. The SOI wafer may include the carrier substrate and an insulating layer on the carrier substrate. This insulating layer may, for example, include a buried oxide (BOX) layer or some other suitable insulating layer.

Semiconductor substrate 102 is formed on such a BOX layer, in embodiments.

A dielectric material layer 104 is formed over and between the FETs 120, including over portions of substrate 102 that are not adjacent and in contact with a FET 120. Dielectric material layer 104 may include silicon oxide, silicon nitride, silicon oxynitride, SiBCN, SiOCN, SiOC, or any suitable combination of those materials. Dielectric material layer 104 may be formed using, for example, chemical vapor deposition (CVD), plasma enhanced chemical vapor deposition (PECVD), physical vapor deposition (PVD), sputtering, or atomic layer deposition. An upper surface of dielectric material layer 104 is planarized using chemical-mechanical polishing (“CMP”). As indicated in FIG. 1, the CMP process may not provide a perfectly planar surface, thus leaving some surface irregularities 130. These surface irregularities 130, if present during later bonding stages, may prevent proper bonding of bonding insulators.

Referring now to FIG. 2, illustrated is the formation of an etch stop layer 106 overlying and in contact with the dielectric material layer 104. Etch stop layer 106 is designed to resist certain chemical etchants. Etch stop layer 106 may include any of silicon oxide, silicon nitride, silicon oxynitride, SiBCN, SiOCN, SiOC, or any suitable combination of those materials. Etch stop layer 106 may be formed using, for example, chemical vapor deposition (CVD), plasma enhanced chemical vapor deposition (PECVD), physical vapor deposition (PVD), sputtering, or atomic layer deposition. Etch stop layer may be formed, for example, to a thickness of about 10 to about 20 nm. As a result of depositing etch stop layer 106, the surface irregularities 130 of the dielectric material layer 104 are filled in (134). In the example illustrated in FIG. 2, irregularities 132 remain on the exposed surface of etch stop layer 106 opposite the interface with the dielectric material layer 104. As illustrated, irregularities 132 are smaller in magnitude than surface irregularities 130. Of note, in some use cases the relative sizes of irregularities 132 and surface irregularities 130 may differ from what is shown in FIG. 2. In some embodiments, for example, etch stop layer 106 may be very smooth, and thus irregularities 132 may practically not exist.

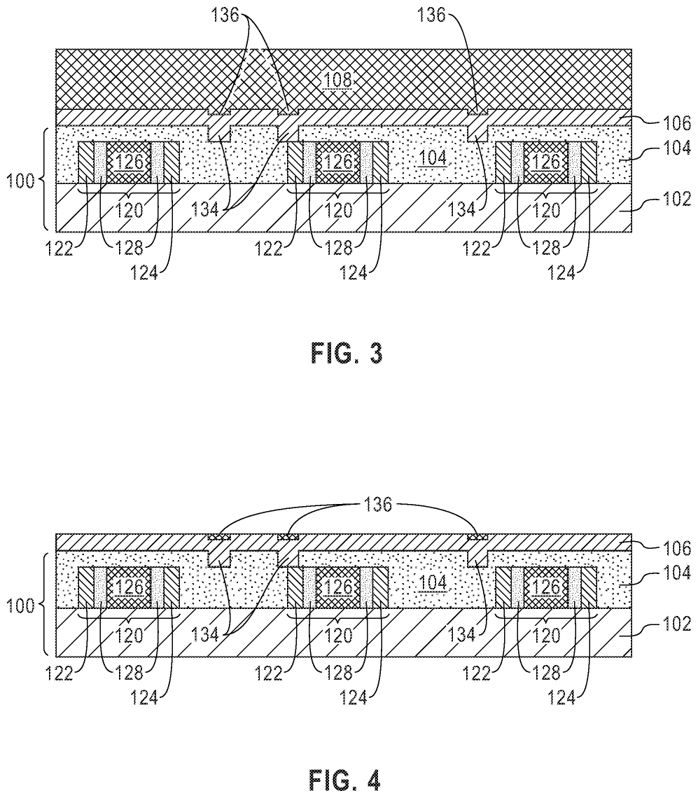

The formation of an insulating material layer 110 is illustrated in FIGS. 3-5. As shown in FIG. 3, a sacrificial insulator layer 108 is deposited directly on etch stop layer 106. The sacrificial insulator layer 108 is a different material that etch stop layer 106, and is selected to be able to be removed by an etchant that does not etch stop layer 106. For example, the material for sacrificial insulator layer 108 may be any of silicon oxide, silicon nitride, silicon oxynitride, SiBCN, SiOCN, SiOC, or any suitable combination of those materials. Sacrificial insulator layer 108 may be formed using, for example, chemical vapor deposition (CVD), plasma enhanced chemical vapor deposition (PECVD), physical vapor deposition (PVD), sputtering, or atomic layer deposition. In the example illustrated in FIG. 3, the surface irregularities 132 of the etch stop layer 106 are filled in (136) as a result of depositing the sacrificial insulator layer 106.

FIG. 4 depicts the subsequent removal of sacrificial insulator layer 108 to the surface of the etch stop layer 106 using a suitable etchant. The etchant may be selected so as to be able to etch away the sacrificial insulator layer 108 while not etching any of the etch stop layer 106 material. Examples of wet etchants include, for example, hydrofluoric acid, phosphoric acid, potassium hydroxide, EDP, and tetramethylammonium hydroxide. Examples of plasma etchants include, for example, carbon tetrachloride and tetrafluoromethane. As such, the etching process removes the sacrificial insulator layer 108 from its outer exposed surface towards the etch stop layer 106, wherein etching ceases to occur. The filled in portions 136 remain below the surface of etch stop layer 106, which include sacrificial insulator material that has not been etched-away due to the fact that it is located below the outer exposed surface of the etch stop layer 106 after etching has ceased. Any residual irregularities in the “top” portion of etch stop layer 106 that were caused by surface irregularities 130 have been eliminated, causing a very smooth surface. As a result, an insulating material layer formed upon the etch stop layer 106 would also likely have a very smooth surface, and therefore would not require much, if any, polishing before bonding. As a result, that insulating material layer could also be applied as a very thin layer, which could improve overall device performance.

While, as depicted in FIG. 4, all of sacrificial material 108 aside from the filled in portions 136 has been etched completely away from etch-stop 106, in practice it is possible for a thin layer of sacrificial insulator layer 108 to remain after the CMP process. This may be, for example, due to irregularities in the etch-stop layer 106 or due to CMP being stopped before completely reaching etch-stop layer 106.

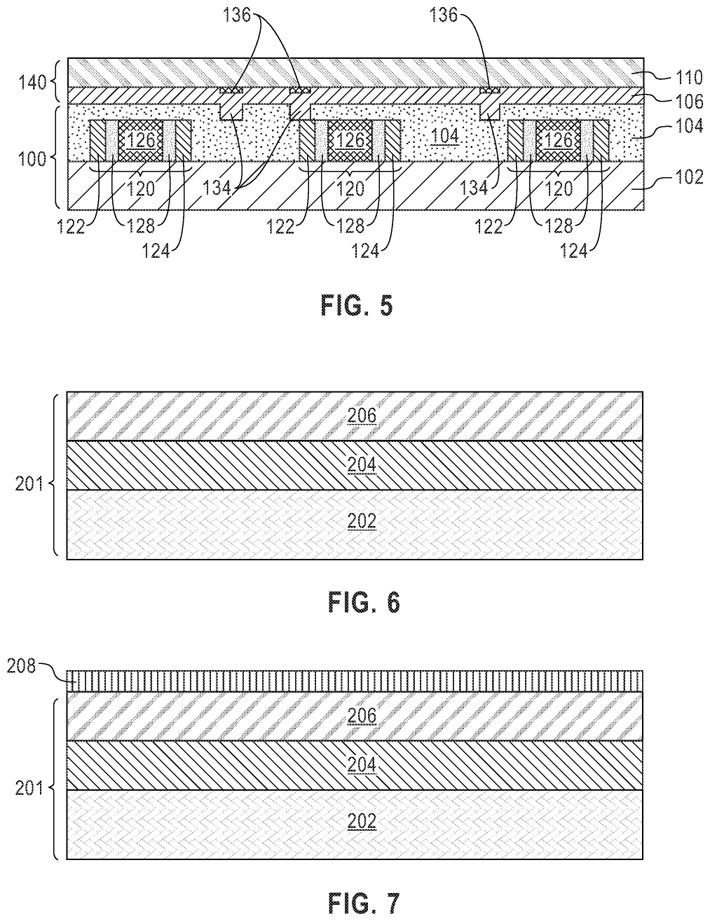

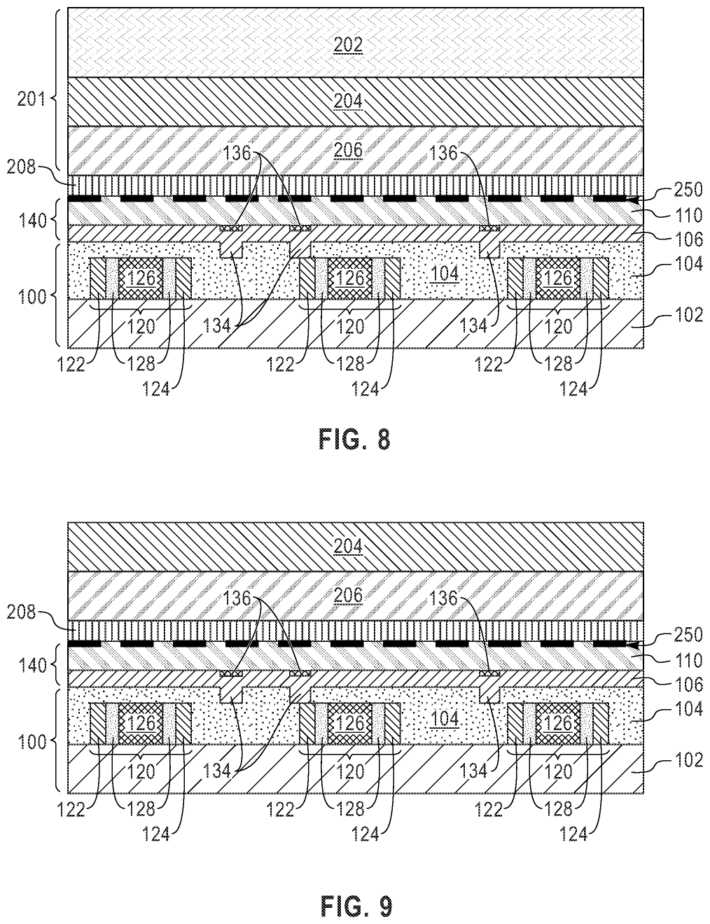

Thereafter, referring now to FIG. 5, the insulating material layer 110 is accomplished by depositing over the exposed surface of etch stop layer 106 one or more materials that may be the same or different as the sacrificial insulator layer 108. An outer exposed surface of the insulating material layer 110 provides one surface of a bonding plane that will be bonded to a second level (non-structural) IC device, as will be discussed in greater detail below in connection with FIG. 8. In some embodiments, the insulating material layer 110 may include multiple layers of differing materials, although in embodiments only one material layer is provided. These layer(s) of materials forming insulating material layer 110 may, for example, include any of silicon oxide, silicon nitride, silicon oxynitride, SiBCN, SiOCN, SiOC, or any suitable combination of those materials. Insulating material layer 110 may be formed using, for example, chemical vapor deposition (CVD), plasma enhanced chemical vapor deposition (PECVD), physical vapor deposition (PVD), sputtering, or atomic layer deposition. Insulating material layer 110 may be formed, for example, to a thickness of about 5 to about 15 nm. In some embodiments, insulating material layer 110 is planarized using CMP to ensure a smooth bonding interface. In the example illustrated in FIG. 5, the combination of etch stop layer 106 and insulating material layer 110 form a bonding insulator 140 of the first level IC 100. Bonding insulator 140 may have a thickness of about 15 to about 35 nm.

Turning now to FIG. 6, illustrated is a cross-section view of semiconductor template stack 201 that will be formed into a second level or “non-structural” integrated circuit (IC) device having a plurality of field effect transistors (FETs) in accordance with embodiments of the present disclosure. The series of layers illustrated in FIG. 6 include a substrate carrier layer 202, an etch stop layer 204 overlying and in direct adjacent contact with the substrate carrier layer 202, and a semiconductor template layer 206 overlying and in direct adjacent contact with the etch stop layer 204. The material forming the substrate carrier layer 202 may be, for example, any of a variety of insulative or semiconductor materials such as, for example, silicon, fused silica (glass, quartz), ceramic, or another semiconductor or insulator. The material forming the etch stop layer 204 may be, for example, any of silicon oxide, silicon nitride, silicon oxynitride, SiBCN, SiOCN, SiOC, or any suitable combination of those materials. The material forming the semiconductor template layer 206 may be, for example, any material that can be configured to exhibit semiconductor properties including, for example, Si, Ge, SiGe, SiC, SiGeC, a II/VI compound semiconductor or a III/V compound semiconductor such as, for example, InAs, GaAs, or InP.

Referring now to FIG. 7, a bonding insulator layer 208 is formed overlying and in direct adjacent contact with the semiconductor template layer 206. This effectively makes the bonding insulator layer 208 a single-layer bonding insulator, as opposed to bonding insulator 140. The bonding insulator layer 208 may be, for example, any of silicon oxide, silicon nitride, silicon oxynitride, SiBCN, SiOCN, SiOC, or any suitable combination of those materials. The material of bonding insulator layer 208 may be the same material or a different material as compared with insulating material layer 110. For example, bonding insulator layer 208 and insulating material layer 110 may both be SiO2, in which case insulating material layer 110 would be considered to comprise a material that is the same with respect to a material of bonding insulator layer 208. However, bonding insulator layer 208 could be SiN and insulating material layer 110 could be SiO2, in which case insulating material layer 110 would be said to comprise a material that is different with respect to a material of the bonding insulator layer 208.

Bonding insulator layer 208 may be formed using, for example, chemical vapor deposition (CVD), plasma enhanced chemical vapor deposition (PECVD), physical vapor deposition (PVD), sputtering, or atomic layer deposition. Bonding insulator layer 208 may be formed, for example, to a thickness of about 5 to about 15 nm. In some embodiments, bonding insulator layer 208 is planarized using CMP to ensure a smooth bonding interface.

The outer exposed surface of bonding insulator layer 208 is provided to form a bonding plane with the outer exposed surface of the insulating material layer 110 as described above in connection with FIG. 5. Referring now to FIG. 8, the first level IC 100 is bonded to the structure described above in connection with FIG. 7, for example semiconductor template stack 201, by bonding together the outer exposed surface of the insulating material layer 110 with the outer exposed surface of the bonding insulator layer 208. This bonding is illustrated in FIG. 8 as bonding line 250. Bonding is performed using any suitable dielectric-to-dielectric bonding process known for stacked FET fabrication, such as thermal bonding or adhesive bonding.

As discussed above, in some embodiments bonding insulating material layer 110 may actually be the same material as bonding insulator layer 208. In some use cases of these embodiments, the transition between insulating material layer 110 and bonding insulator layer 208 may be extremely indistinct. In other words, it may be very difficult to identify the location of bonding line 250 because insulating material layer 110 and bonding insulator layer 208 may appear to be a single layer after bonding is complete. However, even in these use cases, insulating material layer 110 and bonding insulator layer 208 are referred to herein as two different layers because they were originally not bonded to each other and originally part of different stacks.

Thus, for the purposes of this disclosure, a multi-layer stacked semiconductor device that is described as having an insulating material layer and a bonding insulator layer should be interpreted as including a multi-layer stacked semiconductor device in which such layers have been completely bonded together and in which the original border (e.g., a bonding line) between those two layers has become unrecognizable such that is it impractical to determine where the original transition between the insulating material layer and the bonding insulator layer occurred.

Of note, the layers on either side of bonding line 250 exhibit asymmetry due to the inclusion of etch-stop layer 106. Specifically, each of IC device 100 and semiconductor template stack 201 are bonded to a bonding insulator on either side of bonding line 250. The bonding insulator to which IC device 100 is bonded is bonding insulator 140, which contains two layers: insulating material layer 110 and etch-stop layer 106. The bonding insulator to which semiconductor template stack 201 is bonded, however, is simply bonding insulator layer 208, which contains only one layer: bonding insulator layer 208.

Viewed from a different perspective, above bonding line 250 there is a single layer (bonding insulator layer 208), between bonding line 250 and the layer within semiconductor template stack 201 that will contain a series of FETS (semiconductive layer 206). However, below bonding line 250 there are two layers (insulating material layer 110 and etch stop layer 106) between bonding line 250 and dielectric material layer 104, which contains a series of FETs (FETs 120). This asymmetry will be exhibited more clearly in later figures (e.g., FIG. 11).

Referring now to FIG. 9, substrate carrier layer 202 is removed, thereby exposing an outer surface of etch stop layer 204. Substrate carrier layer 202 is removed by etching using a suitable chemical etchant that selectively removes the material of substrate carrier layer 202 while not removing any of etch stop layer 204. As such, the etching process removes the substrate carrier layer 202 from its outer exposed surface towards the etch stop layer 204, at which point etching ceases to occur.

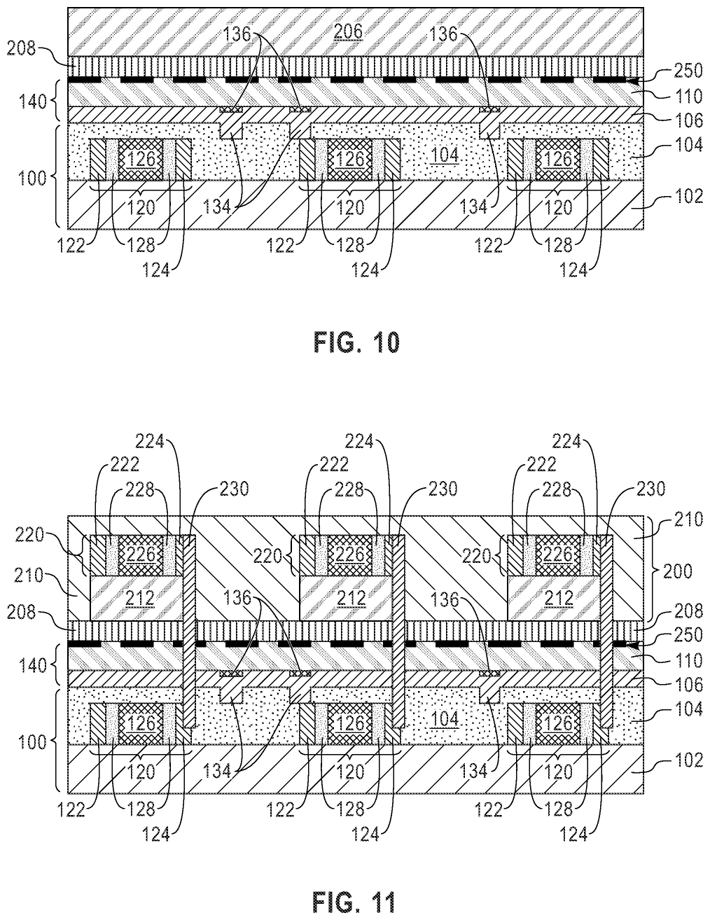

Continuing to FIG. 10, the etch stop layer 204 is subsequently removed, thereby exposing an outer surface of semiconductor template layer 206. Etch stop layer may be removed by any suitable means, such as chemical etching (i.e., using an etchant selective to etch stop layer 204 that is different than the etchant previously used in connection with the removal of substrate carrier layer 202), dry etching, or planarization (CMP). In some embodiments, the manner of removal of the etch stop layer 204 may be selected so as not to remove substantially any of the semiconductor template layer 206.

Referring now to FIG. 11, illustrated is a cross-section view of a second level or “non-structural” integrated circuit (IC) device 200 having a plurality of field effect transistors (FETs) 220 in accordance with embodiments of the present disclosure. Second level IC device 200 is formed using the semiconductor template stack 201 described above in FIG. 10, as will be described in an example process below.

First, semiconductor template layer 206 may have been patterned and etched into individual, spaced-apart segments 212, which may be regularly or irregularly spaced. Patterning may have been performed using a lithographic masking and patterning processes. An etchant may have been applied and non-masked areas of the semiconductor template layer 206 were removed, resulting in the segments 212.

FETs 220 may have been thereafter formed overlying and in direct adjacent contact with each of the segments 212. Each FET 220 includes a gate structure 226. Each gate structure 226 includes a gate dielectric portion and a gate conductor portion (not separated illustrated in the view of FIG. 1). Furthermore, FETs 220 each include a source region 222 and a drain region 224. Each source region 222 and drain region 224 include a silicon material that includes an appropriate dopant, of either the n-type or the p-type. The source regions 222 and the drain regions 224 are provided in the areas shown in FIG. 11, that is, areas lateral to but not covered by gate structures 226. The source and drain regions 222, 224 may be separated from the gate structures 226 using appropriate dielectric spacers 228, which include an insulative material such as silicon oxide.

A dielectric material layer 210 is formed over and between the FETs 220 and segments 212, including over portions of the bonding insulator layer 208 that are not adjacent to and in contact with a segment 212. Dielectric material layer 210 may include, for example, silicon oxide, silicon nitride, silicon oxynitride, SiBCN, SiOCN, SiOC, or any suitable combination of those materials. Dielectric layer material layer 210 may be formed using, for example, chemical vapor deposition (CVD), plasma enhanced chemical vapor deposition (PECVD), physical vapor deposition (PVD), sputtering, or atomic layer deposition. An upper surface of dielectric layer 210 is planarized using CMP to the gate structures 226.

Thereafter, local interconnect conductive structures 230 are formed to establish an electrical connection between the first level IC device 100 and the second level IC device 200. For example, a photoresist mask may be formed overlying the dielectric material layer 210 using deposition and photolithography, in which the openings in the photoresist mask correspond to the portions of the dielectric layer that are etched. Once the patterning of the photoresist is completed, the sections covered by the photoresist may be protected while the exposed regions are removed using a selective etching process that removes the unprotected regions. The exposed portions of dielectric material layer 210 may then be etched to provide the openings. The etch process for forming the openings may include an anisotropic etch, such as reactive ion etch, laser etching, plasma etching, or a combination thereof.

A conductive metallic contact material is formed within the openings. The metallic contact material forms local interconnect structures 230 extending from the drain regions 224 of the second level IC device 200, then through the bonding insulator layer 208, then through the bonding insulator 140, then through the dielectric material layer 104, and thereafter to drains 124 of the FETs 120. Thereafter, additional insulator 210 is formed over the local interconnects 230 and gate structures 226, as illustrated.

Of note, bonding insulator 140 of the first level IC device 100 and bonding insulator 208 of second level IC device 200 serve similar purposes in that they provide insulation from their respective IC devices (i.e., IC devices 100 and 200). However, bonding insulator 140 and bonding insulator layer 208 are considered “asymmetrical” herein. This is because bonding insulator 140 contains two layers (insulating material layer 110 and etch stop layer 106) whereas bonding insulator layer 208 is a single layer.

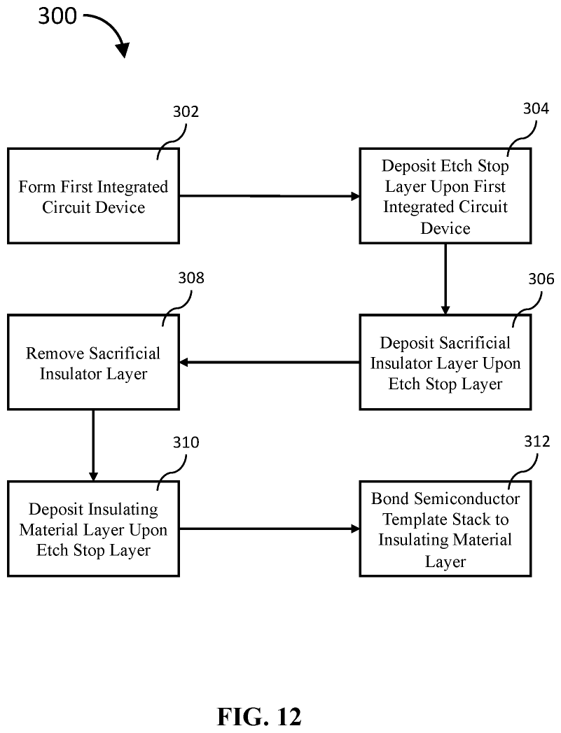

FIG. 12 is a process flow diagram illustrating an exemplary method 300 for fabricating a stacked IC device in accordance with embodiments of the present disclosure. Method 300 begins with block 302, which includes forming an integrated circuit device. The first integrated circuit device may contain a first layer field-effect transistor (FET). Method 300 continues with block 304, which includes depositing an etch stop layer upon the first integrated circuit device. Method 300 continues with block 306, which includes forming sacrificial insulator layer upon the etch stop layer.

Method 300 continues with block 308, which includes removing the sacrificial insulator layer.

In some embodiments, removing the sacrificial layer may take the form of polishing the sacrificial insulator layer utilizing CMP that is selective to the etch-stop layer. CMP that is selective to the etch stop layer may refer to performing CMP with a polishing chemical that causes the speed of polishing to noticeably decrease when the sacrificial layer is mostly removed and the etch-stop layer is reached. For example, the rate at which the polishing chemical corrodes the sacrificial insulator layer may be significantly higher than the rate at which the polishing chemical corrodes the etch-stop layer.

The combination of blocks 306 and 308 may effectively fill any surface irregularities upon the etch stop layer, causing the etch stop layer to have a substantially flat surface.

Method 300 continues with block 310, which includes depositing an insulating material layer upon the etch stop layer. In some embodiments, this insulating material layer may be the same material as the sacrificial insulator layer. In some use cases, depositing the insulating material layer in block 310 may be referred to as touching up with the insulating material layer.

Method 300 continues with block 312, which includes bonding a semiconductor template stack to the insulating material layer that was deposited in block 310. Following block 312, the semiconductor template stack could be formed into a second integrated circuit device.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that use of descriptions such as top, bottom, left, right, vertical, horizontal, or the like, are intended to be in reference to the orientation(s) illustrated in the figures, and are intended to be descriptive and to distinguish aspects of depicted features without being limiting. Spatially relative terms, such as “beneath,” “below,” “lower,” “above,” “upper,” and the like, may be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below, depending on the context. The device may be otherwise oriented (rotated 90 degrees or at other orientations), and the spatially relative descriptors used herein may be interpreted accordingly. In addition, it will also be understood that when a layer is referred to as being “between” two layers, it can be the only layer between the two layers, or one or more intervening layers may also be present.

It will be understood that, although the terms first, second, etc. may be used herein to describe various elements, these elements should not be limited by these terms. These terms are only used to distinguish one element from another element. Reference to first, second, third, etc., feature is intended to distinguish features without necessarily implying a particular order unless otherwise so stated or indicated. Thus, a first element discussed herein could be termed a second element without departing from the scope of the present concept.

The present embodiments may include a design for an integrated circuit chip, which may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

What is claimed is:

1. A multi-layer stacked semiconductor device comprising:
a first integrated circuit device;
a bonding insulator formed upon the first integrated circuit device, wherein the bonding insulator comprises an insulating material layer and an etch stop layer;
a second integrated circuit device formed over the first integrated circuit device in a stacked configuration; and
a bonding insulator layer formed between the second integrated circuit device and the insulating material layer;
wherein the insulating material layer and the bonding insulator layer are bonded adjacent to one another.

2. The semiconductor device of claim 1, wherein the insulating material layer comprises a material that is different with respect to a material of the bonding insulator layer.

3. The semiconductor device of claim 1, wherein the insulating material layer comprises a material that is the same with respect to a material of the bonding insulator layer.

4. The semiconductor device of claim 1, wherein the insulating material layer comprises a silicon oxide material.

5. The semiconductor device of claim 1, wherein the first integrated circuit device comprises a first layer field-effect transistor (FET) and wherein the second integrated circuit device comprises a second layer FET.

6. The semiconductor device of claim 5, further comprising a local interconnect electrical connection connecting the first layer FET to the second layer FET.

7. The semiconductor device of claim 6, wherein the local interconnect electrical connection connects a terminal of the first layer FET to a terminal of the second layer FET.

8. The semiconductor device of claim 5, wherein the first layer FET and the second layer FET are selected from planar FETs and finFETs.

9. The semiconductor device of claim 1, wherein the insulating material layer has a thickness of about 15 nm to about 35 nm.

10. The semiconductor device of claim 1, wherein the etch stop layer has a thickness of about 10 nm to about 20 nm.

11. A method for fabricating a multi-layer stacked semiconductor device, the method comprising:
depositing an etch stop layer upon a first integrated circuit device;
depositing a sacrificial insulating layer upon the etch stop layer;
removing the sacrificial insulator layer;
depositing an insulating material layer upon the etch stop layer; and
bonding a semiconductor template stack to the insulating material layer.

12. The method of claim 11, further comprising forming an integrated circuit device using the semiconductor template stack.

13. The method of claim 12, wherein the first integrated circuit device comprises a first layer field-effect transistor (FET) and the second integrated circuit device comprises a second layer FET.

14. The method of claim 11, wherein removing the sacrificial insulator layer comprises performing chemical-mechanical polishing that is selective to the etch-stop layer.

15. The method of claim 11, wherein bonding the semiconductor template stack to the insulating material layer comprises bonding a bonding insulator layer in the semiconductor template stack to the insulating material layer.

16. The method of claim 15, wherein depositing the insulating material layer comprises depositing a material that is different with respect to a material of the bonding insulator layer.

17. The method of claim 15, wherein depositing the insulating material layer comprises depositing a material that is the same with respect to a material of the bonding insulator layer.

18. The method of claim 13, further comprising forming a local interconnect electrical connection connecting the first layer FET to the second layer FET.

19. The method of claim 11, depositing the insulating material layer comprises depositing the insulating material layer to a thickness of about 5 nm to about 15 nm depositing the etch-stop layer comprises depositing the etch-stop layer to a thickness of about 10-20 nm.

20. A semiconductor chip comprising a multi-layer stacked semiconductor device, the multi-layer stacked semiconductor device comprising:
a first integrated circuit device;
a bonding insulator formed upon the first integrated circuit device, wherein the bonding insulator comprises an insulating material layer and an etch stop layer;
a second integrated circuit device formed over the first integrated circuit device in a stacked configuration; and
a bonding insulator layer formed between the second integrated circuit device and the insulating material layer:
wherein the insulating material layer and the bonding insulator layer are bonded adjacent to one another.
